(19) United States
(12) Patent Application Publication
(10) Pub. No.: US 2006/0066333 A1
(43) Pub. Date: Mar. 30, 2006

(54) System and method for aligning wafers

(76) Inventors: Jian-Huei Feng, San Jose, CA (US); Hung-Chin Guthrie, Saratoga, CA (US); James Nystrom, Sunnyvale, CA (US)

Correspondence Address: WAGNER, MURABITO & HAO LLP, Third Floor, Two North Market Street, San Jose, CA, 95113, US

(21) Appl. No.: 10/956,801

(22) Filed: Sep. 30, 2004

(51) Int. Cl. G01R 31/02

(52) U.S. Cl. 324/758

(57) ABSTRACT

Systems and methods for aligning wafers. A first method provides for placing a wafer carrier comprising a mis-aligned wafer into an acceptance port. A wafer alignment fixture is moved relative to the wafer carrier and perpendicular to the plane of the mis-aligned wafer. The wafer alignment fixture comprises a spring action member. A force from said spring action member is exerted upon the mis-aligned wafer to achieve a desirable alignment of the mis-aligned wafer within the wafer carrier.

### TECHNICAL FIELD

Embodiments of the present invention relate to the fields of manufacturing semiconductors and hard disk drives, and more particularly to systems and methods for aligning wafers as utilized in the manufacture of semiconductors and hard disk drives.

### BACKGROUND ART

Hard disk drives are used in almost all computer system operations. In fact, most computing systems are not operational without some type of hard disk drive to store the most basic computing information such as the boot operation, the operating system, the applications, and the like. In general, the hard disk drive is a device which may or may not be removable, but without which the computing system will generally not operate.

The basic hard disk drive model was established approximately 40 years ago and resembles a phonograph. That is, the hard drive model includes a plurality of storage disks or hard disks vertically aligned about a central core that spin at a standard rotational speed. A plurality of magnetic read/write transducer heads, for example, one head per surface of a disk, is mounted on the actuator arm. The actuator arm is utilized to reach out over the disk to or from a location on the disk where information is stored. The complete assembly, e.g., the arm and head, is known as a head gimbal assembly (HGA).

In operation, the plurality of hard disks is rotated at a set speed via a spindle motor assembly having a central drive hub. Additionally, there are channels or tracks evenly spaced at known intervals across the disks. When a request for a read of a specific portion or track is received, the hard disk drive aligns a head, via the arm, over the specific track location and the head reads the information from the disk. In the same manner, when a request for a write of a specific portion or track is received, the hard disk drive aligns a head, via the arm, over the specific track location and the head writes the information to the disk.

Over the years, refinements of the disk and the head have provided great reductions in the size of the hard disk drive. For example, the original hard disk drive had a disk diameter of 24 inches. Modem hard disk drives are generally much smaller and include disk diameters of less than 2.5 inches (micro drives are significantly smaller than that). Refinements also include the use of smaller components and laser advances within the head portion. That is, by reducing the read/write tolerances of the head portion, the tracks on the disk can be reduced in size by the same margin. Thus, as modern laser and other micro recognition technology are applied to the head, the track size on the disk can be further compressed.

A second refinement to the hard disk drive is the increased efficiency and reduced size of the spindle motor spinning the disk. That is, as technology has reduced motor size and power draw for small motors, the mechanical portion of the hard disk drive can be reduced and additional revolutions per minute (RPM) can be achieved. For example, it is not uncommon for a hard disk drive to reach speeds of 15,000 RPM. This second refinement provides weight and size reductions to the hard disk drive and increases the linear density of information per track. Increased rates of revolution also provide a faster read and write rate for the disk and decrease the latency, or time required for a data area to become located beneath a head, thereby providing increased speed for accessing data. The increase in data acquisition speed due to the increased RPM of the disk drive and the more efficient read/write head portion provide modern computers with hard disk speed and storage capabilities that are continually increasing.

A wafer is a basic “building block” upon which numerous processing actions take place to produce semiconductor devices. Wafers also form a similar building block for the production of magnetic read and/or write heads and disks as used in hard disk drives. The production of such devices can comprise many different processing steps. It is not uncommon for hundreds of operations to be performed on wafers. Frequently, such production processes require that wafers be moved from one machine to another. Generally, wafers are grouped together for such transport between machines or storage. Wafers are typically moved among a variety of wafer processing equipment in wafer carriers known as cassettes. Sometimes such a cassette is also known as a “boat.”

A cassette is generally constructed from an engineering plastic. It typically comprises a plurality of slots that support and isolate each wafer. A cassette may hold up to about two dozen wafers, sometimes more. Although there are a variety of styles of cassettes available from a variety of manufacturers, a cassette is typically closed on top and bottom surfaces and closed on three sides. A fourth side is typically open, allowing for individual wafers to be moved in and out of the cassette by wafer processing equipment.

When viewed in cross section, a cassette may have a generalized “C” shape. For example, the top, bottom and back of the “C” shape are closed, while the front of the “C” shape is open. The wafers are moved in and out of such openings.

Unfortunately, wafers sometimes do not maintain a desired alignment within a cassette. For example, various handling operations, e.g., a “bump,” of a cassette can dislodge one or more wafers from their desired position within the cassette. Further, errors by automated wafer handling equipment can sometimes incorrectly place a wafer into a cassette.

Such misaligned wafers can frequently cause a processing disruption at a subsequent processing stage. For example, a wafer that is misaligned in a cassette can be incorrectly accessed by a processing device. Such an incorrect access can result in incorrect placement of a wafer within the processing device. Typically, after a time-out interval, the processing device will detect the incorrect placement of the wafer and reject that wafer. A common response to such a situation stops production flow and requires manual intervention to restore normal production. Manual intervention is not only costly in terms of direct costs and production delays, but further has the potential to introduce deleterious contamination onto the wafer and/or into the processing equipment. Contamination thus introduced can result in defects that have a detrimental effect upon production yield. In some cases, such defects may not be detected until much later in a production process.

Accordingly, there is a need for systems and methods for aligning wafers. Additionally, in conjunction with the aforementioned need, systems and methods for automatically aligning wafers while minimizing contamination opportunities are desired. A further need, in conjunction with the aforementioned needs, is for aligning wafers in a manner that is compatible and complimentary with existing wafer processing systems and manufacturing processes.

### SUMMARY

Systems and methods for aligning wafers are disclosed. A first method provides for placing a wafer carrier comprising a mis-aligned wafer into an acceptance port. A wafer alignment fixture is moved relative to the wafer carrier and perpendicular to the plane of the mis-aligned wafer. The wafer alignment fixture comprises a spring action member. A force from said spring action member is exerted upon the mis-aligned wafer to achieve a desirable alignment of the mis-aligned wafer within the wafer carrier.

### BRIEF DESCRIPTION OF THE DRAWINGS

FIG. 1 illustrates a side-sectional view of a wafer alignment fixture, in accordance with embodiments of the present invention.

FIG. 2A illustrates an exemplary cassette loaded with a plurality of wafers, in accordance with embodiments of the present invention.

FIG. 2B illustrates loading a cassette into a cassette acceptance port of an exemplary wafer processing unit, in accordance with embodiments of the present invention.

FIG. 3 illustrates a method of aligning wafers, in accordance with embodiments of the present invention.

FIG. 4 is a flow chart for a method of automatically aligning a mis-aligned wafer, in accordance with embodiments of the present invention.

### BEST MODES FOR CARRYING OUT THE INVENTION

Reference will now be made in detail to the alternative embodiment(s) of the present invention, system and method for aligning wafers. While the invention will be described in conjunction with the alternative embodiment(s), it will be understood that they are not intended to limit the invention to these embodiments. On the contrary, the invention is intended to cover alternatives, modifications and equivalents, which may be included within the spirit and scope of the invention as defined by the appended claims.

Some portions of the detailed descriptions that follow (e.g., method 400) are presented in terms of procedures, steps, logic blocks, processing, and other symbolic representations of operations on data bits that can be performed on computer memory. These descriptions and representations are the means used by those skilled in the data processing arts to most effectively convey the substance of their work to others skilled in the art. A procedure, computer executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present invention, discussions utilizing terms such as “placing” or “moving” or “determining” or “calculating” or “delaying” or “measuring” or “terminating” or “initiating” or “locating” or “indicating” or “transmitting” or “receiving” or “advancing” or “comparing” or “processing” or “computing” or “translating” or “determining” or “excluding” or “displaying” or “recognizing” or “generating” or “assigning” or “initiating” or “collecting” or “transferring” or “switching” or “accessing” or “retrieving” or “receiving” or “issuing” or “measuring” or “conveying” or “sending” or “dispatching” or “advancing” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Furthermore, in the following detailed description of the present invention, numerous specific details are set forth in order to provide a thorough understanding of the present invention. However, it will be recognized by one of ordinary skill in the art that the present invention may be practiced without these specific details. In other instances, well known methods, procedures, components, and circuits have not been described in detail as not to unnecessarily obscure aspects of the present invention.

### System and Method for Aligning Wafers

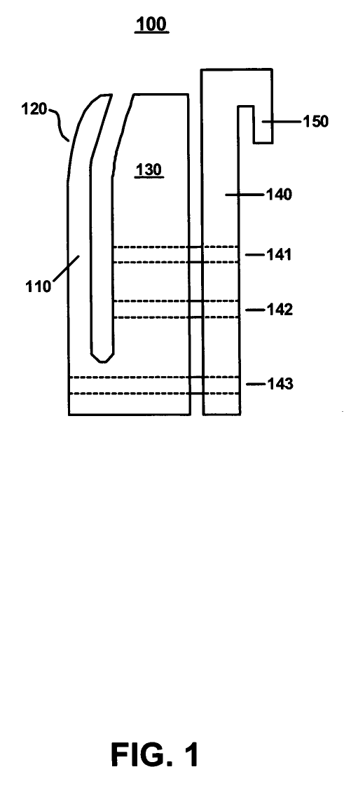

FIG. 1 illustrates a side-sectional view of a wafer alignment fixture 100, in accordance with embodiments of the present invention. Wafer alignment fixture 100 can be constructed from a variety of materials. However, embodiments of the present invention should be made from materials that are chemically compatible with wafers, processing equipment and processing chemicals, and do not readily contribute contaminants, e.g., via outgassing or flaking, to the processing environment. For example, embodiments of the present invention are well suited to the use of polypropylene plastic.

Wafer alignment fixture 100 comprises a cantilever arm 110. Via well known techniques of analysis, physical parameters of cantilever arm 110, e.g., type of material, shape, thickness and the like, can be determined such that cantilever arm 110 acts as a spring. That is, in the plane of FIG. 1, cantilever arm 110 can be moved either toward or away from body 130 of wafer alignment fixture 100. In addition, cantilever arm 110 generates a restorative force that resists movement away from an “at rest” or nominal position of cantilever arm 110.

As viewed in FIG. 1, the top left portion of cantilever arm 110 is tilted away from the exterior edge of cantilever arm 110 forming guide region 120. Guide region 120 is illustrated as substantially following a smooth curve. It is appreciated, however, that embodiments in accordance with the present invention are well suited to a variety of shapes for guide region 120, for example, a chamfer.

In accordance with one embodiment of the present invention, wafer alignment fixture 100 is approximately 27 cm tall and about 1 cm thick (dimension not shown in FIG. 1). Body 130 and cantilever arm 110 together are approximately 5 cm wide. Guide region 120 comprises a region of about 5 cm from the top of cantilever arm 110

In accordance with the same embodiment of the present invention, cantilever arm 110 is about 1 cm wide. The gap between cantilever arm 110 and body 130 begins approximately 3 cm from the bottom of wafer alignment fixture 100. The gap between cantilever arm 110 and body 130 is about 1 cm wide.

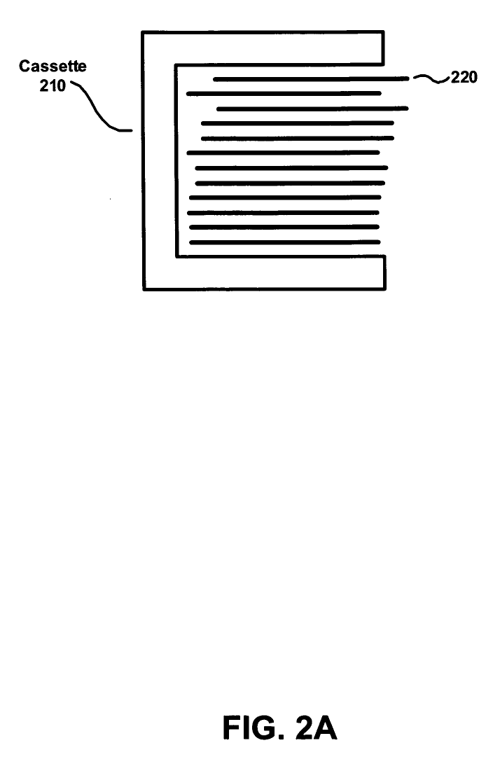

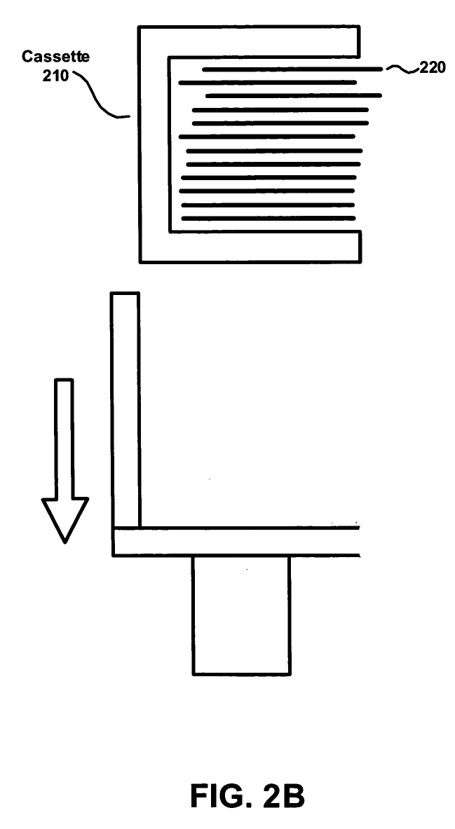

FIG. 2A illustrates an exemplary cassette 210 loaded with a plurality of wafers, in accordance with embodiments of the present invention. It is appreciated that some of those wafers, e.g., wafer 220, are mis-aligned. For example, various handling operations, e.g., a “bump,” of a cassette can dislodge one or more wafers from their desired position within the cassette. Further, errors by automated wafer handling equipment can sometimes incorrectly place a wafer into a cassette.

FIG. 2B illustrates loading cassette 210 into a cassette acceptance port of an exemplary wafer processing unit, in accordance with embodiments of the present invention. A cassette acceptance port will generally have a similar cross-sectional shape as cassette 210. Cassette 210 is generally placed on a cassette elevator and lowered automatically into the wafer processing equipment. Sometimes, the cassette is lowered into a cleaning media, e.g., a bath of deionized water.

As discussed previously, misaligned wafers, e.g., wafer 220, can frequently cause a processing disruption at a processing stage. For example, a wafer that is misaligned in a cassette can be incorrectly accessed by a processing device. Such an incorrect access can result in incorrect placement of a wafer within the processing device. Typically, after a time-out interval, the processing device will detect the incorrect placement of the wafer and reject that wafer.

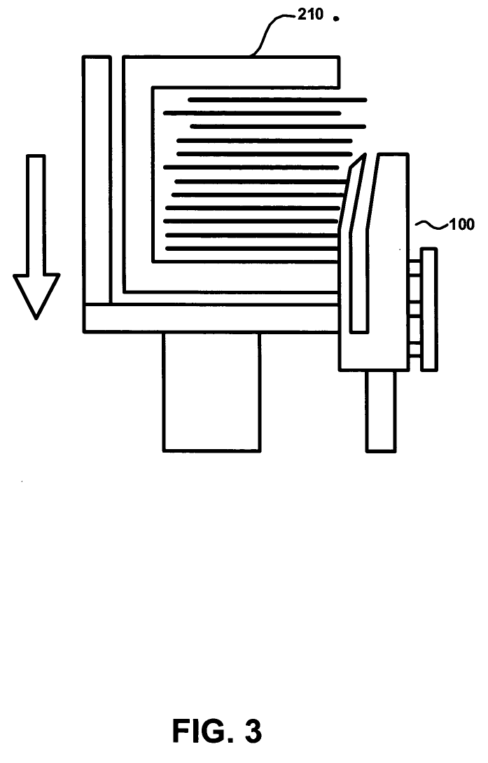

Referring now to FIG. 3, wafer alignment fixture 100 is depicted aligning wafers in cassette 210 as cassette 210 is lowered into a unit of wafer processing equipment. Guide region 120 and a spring action of cantilever arm 110 exert a force upon mis-aligned wafers to place such wafers into a properly aligned position within cassette 210.

Referring once again to FIG. 1, wafer alignment fixture 100 is further illustrated with optional mounting bracket 140. Mounting bracket 140 enables wafer alignment fixture 100 to be mounted to a non-vertical vertical mounting surface. For example, wafer alignment fixture 100 can be mounted to a side of a wafer washing station. When the wafer washing station is filled with washing liquid, the sides or walls of the washing station can be distorted or “bowed” by the pressure of the washing liquid. In general, such distorted walls will be out of vertical. More particularly, the walls of such a washing station may not be exactly parallel with a desired vertical plane of alignment for the wafers of cassette 210 (FIG. 3).

In accordance with an embodiment of the present invention, mounting bracket 140 can be mounted to a wall of a wafer washing station, or any other cassette acceptance port, e.g., a “sending station” or a “receiving” station, that is not vertical. Wafer alignment fixture 100 can then be attached via screws 141, 142 and 143 to mounting bracket 140 in order to compensate for an angular difference between a mounting surface of a cassette acceptance port and a desired plane of wafer alignment. For example, there can be a varying separation between lower portions of body 130 and mounting bracket 140 in comparison to upper portions of body 130 and mounting bracket 140.

Still referring to FIG. 1, mounting bracket 140 comprises an optional lip 150. Lip 150 enables mounting bracket 140 and/or wafer alignment fixture 100 to be hooked over an appropriate edge of a cassette acceptance port, for example a wafer washing tank.

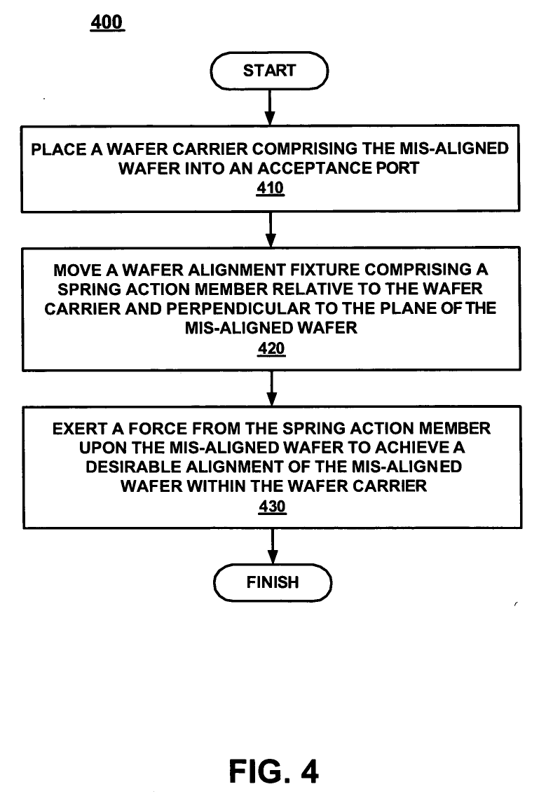

FIG. 4 is a flow chart for a method 400 of automatically aligning a mis-aligned wafer, in accordance with embodiments of the present invention. In 410, a wafer carrier comprising the mis-aligned wafer, for example a cassette, is placed into an acceptance port. Acceptance ports can comprise, for example, wafer washing stations, receiving ports or sending ports.

In 420, a wafer alignment fixture comprising a spring action member is moved perpendicular to the plane of the mis-aligned wafer. For example, a wafer cassette comprising the mis-aligned wafer can be moved past a stationary wafer alignment fixture. Such a movement can be a part of a loading or unloading process performed to load a cassette into, or remove a cassette from wafer processing equipment. Alternatively, a wafer alignment fixture can be moved past a stationary or moving wafer cassette.

In 430, the spring action member exerts a force upon the mis-aligned wafer causing the mis-aligned wafer to achieve a desirable alignment within the wafer carrier.

Thus, embodiments of the present invention provide an apparatus and method for aligning wafers. Additionally, embodiments provide a method and system for correcting both single plane and coupled plane imbalances in a disk stack. Embodiments of the present invention further provide for balancing disk assemblies in a manner that is compatible and complimentary with existing hard disk systems and manufacturing processes.

While the method of the embodiment illustrated in flow chart 400 shows specific sequences and quantity of steps, the present invention is suitable to alternative embodiments. For example, not all the steps provided for in the methods are required for the present invention. Furthermore, additional steps can be added to the steps presented in the present embodiment. Likewise, the sequences of steps can be modified depending upon the application.

Embodiments in accordance with the present invention, system and method for aligning wafers, are thus described. While the present invention has been described in particular embodiments, it should be appreciated that the present invention should not be construed as limited by such embodiments, but rather construed according to the below claims.

1. A wafer alignment fixture comprising:
a body portion; and
a spring mechanism coupled to said body portion;
wherein said spring mechanism is configured to contact a wafer and apply a restorative force of said spring mechanism to move said wafer into a desirable alignment within a wafer carrier.

2. The wafer alignment fixture of claim 1 wherein said spring mechanism comprises a cantilever arm.

3. The wafer alignment fixture of claim 2 wherein said cantilever arm comprises a guide region for accommodating a wafer extending beyond a projection of an edge of said wafer alignment fixture.

4. The wafer alignment fixture of claim 1 further comprising a mounting bracket for adjusting alignment of said wafer alignment fixture.

5. The wafer alignment fixture of claim 4 wherein said alignment of said wafer alignment fixture is vertical.

6. The wafer alignment fixture of claim 5 wherein said mounting bracket is attached to a non-vertical mounting surface.

7. The wafer alignment fixture of claim 1 further comprising a hook feature for attaching said wafer alignment fixture over an edge of wafer processing equipment.

8-14. (canceled)

15. A wafer alignment fixture for aligning a mis-aligned wafer comprising:
body means; and
spring action means coupled to said body means for exerting a force upon said mis-aligned wafer to achieve a desirable alignment of said mis-aligned wafer within said wafer carrier.

16. The wafer alignment fixture of claim 15 wherein said spring action means comprises cantilever means.

17. The wafer alignment fixture of claim 16 wherein said cantilever means comprises guide means for accommodating a wafer extending beyond a projection of an edge of said wafer alignment fixture.

18. The wafer alignment fixture of claim 15 further comprising mounting means for adjusting alignment of said wafer alignment fixture.

19. The wafer alignment fixture of claim 18 wherein said mounting means comprises means to align to a non-vertical mounting surface.

20. The wafer alignment fixture of claim 15 further comprising hook means for attaching said wafer alignment fixture over an edge of wafer processing equipment.
